(19) United States
(12) Patent Application Publication
(10) Pub. No.: US 2026/0245487 A1
(43) Pub. Date: Aug. 20, 2026

(54) APPARATUS AND METHOD FOR DETECTING STAIN OF DISPLAY DEVICE

(71) Applicant: Samsung Display Co., LTD., Yongin-si (KR)

(72) Inventors: Se Kwang HAN, Yongin-si (KR); Joon Geol KIM, Yongin-si (KR); Gi Joung JANG, Yongin-si (KR)

(21) Appl. No.: 19/398,473

(22) Filed: Nov. 24, 2025

(30) Foreign Application Priority Data
Feb. 19, 2025 (KR) 10-2025-0021415

(51) Int. Cl. G09G 3/00; G06T 7/00

(52) U.S. Cl. CPC G09G 3/006; G06T 7/001; G06T 2207/30108

(57) ABSTRACT

Embodiments include a method for detecting a stain of a display device. The method includes outputting array test data of the display device from an array tester; transforming the output array test data into multiple transformation data; generating multiple images based on the multiple transformation data, respectively; and determining a stain by comparing and analyzing the generated multiple images, wherein the array test data is a current value of a thin film transistor for each pixel of the display device measured using the array tester.

This application claims priority to Korean Patent Application No. 10-2025-0021415, filed on Feb. 19, 2025, and all the benefits accruing therefrom under 35 U.S.C. § 119, the content of which in its entirety is herein incorporated by reference.

### BACKGROUND

### 1. Technical Field

The present disclosure relates to a method and apparatus for detecting a stain of a display device.

### 2. Description of the Related Art

With recent technological advancements, various types of flat panel display devices are being developed. An organic light emitting display device including an organic light emitting diode (OLED) which is one of the flat panel display devices is a display device that emits light by electrically exciting an organic compound, and is configured to display an image by driving organic light emitting cells arranged in the form of a matrix using voltage or current.

There are passive and active types of a method for driving the organic light emitting display, but the active type is suitable in terms of materials, lifespan, and crosstalk for realizing a large-screen and high-definition display. The active type is a method that connects a thin film transistor to each indium tin oxide (ITO) pixel electrode and drives the organic light emitting cells according to a voltage maintained by a capacitor capacity connected to the thin film transistor. Therefore, an active display panel includes at least one thin film transistor and capacitor in a pixel.

Recently, as the proportion of the flat panel display manufacturing industry is increasing, quality control of these products is becoming an important issue. Accordingly, display device manufacturers are equipped with automatic inspection devices to detect defects, such as stains, that occur during the manufacturing process in advance and strive to maintain the quality level of the products.

In addition, such a display device may be assembled into a module and subjected to full inspection. However, when inspection is performed after being assembled into the module, there is a problem that the cost of waste increases if defective products are produced. Therefore, a method for inspecting a TFT array substrate for defects is required so that defects in elements of a pixel circuit may be discovered in advance before the display device is assembled into the module.

The flat panel display, including the organic light emitting diode (OLED), may include more pixels per unit area to increase resolution. This results in a trend toward a narrowing of a gap between cells, which may limit the ability to inspect stains of various causes.

### SUMMARY

Aspects of the present disclosure provide an apparatus and method for detecting a stain of a display device capable of detecting stains of various causes occurring in a manufacturing process due to advanced patterns.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, a method for detecting a stain of a display device, includes outputting array test data of the display device from an array tester; transforming the output array test data into multiple transformation data; generating multiple images based on the multiple transformation data, respectively; and determining a stain by comparing and analyzing the generated multiple images, where the array test data is a current value of a thin film transistor for each pixel of the display device measured using the array tester.

In an embodiment, in the transforming of the output array test data into the multiple transformation data, the output array test data may be transformed into the multiple transformation data through an operation process including mathematical operations, respectively, and wherein the mathematical operations may include arithmetic operations, differentiation, or integration.

In an embodiment, the operation may include a first operation, and the first operation may calculate a difference between the maximum and minimum values of the current value of the thin film transistor for each pixel of the display device.

In an embodiment, the operation may include a second operation, and the second operation calculates a mean value of the current value of the thin film transistor for each pixel of the display device.

In an embodiment, the operation may include a third operation, and the third operation may calculate a median of the current value of the thin film transistor for each pixel of the display device.

In an embodiment, the operation may include a fourth operation, and the fourth operation may calculate an average rate of change or an instantaneous rate of change of the current value of the thin film transistor for each pixel of the display device.

In an embodiment, the operation may include a fifth operation, and the fifth operation may calculate a y-intercept of a straight line whose slope is an average rate of change or an instantaneous rate of change of the current value of the thin film transistor for each pixel of the display device.

In an embodiment, the operation may include a sixth operation, and the sixth operation may calculate a definite integral value of the current value of the thin film transistor for each pixel of the display device.

In an embodiment, the generating of the multiple images based on the multiple transformation data, respectively, may include mapping corresponding transformation data of the multiple transformation data for each pixel to a location of each pixel in the di splay device and correcting the corresponding transformation data into a gray scale.

In an embodiment, the determining of the stain by comparing and analyzing the generated multiple images may include classifying points in the generated multiple images where a brightness is a certain level or less as stain images, and assigning a weight to each of the classified stain images based on stain determination criteria.

In an embodiment, the determining of the stain by comparing and analyzing the generated multiple images may further include when the weight assigned to the each of the classified stain images is a certain level or more, classifying each of the classified stain image as a stain determination image.

In an embodiment, the determining of the stain by comparing and analyzing the generated multiple images may further include finally determining the stain by comparing the classified stain determination images and analyzing a location and characteristics of the stain.

According to an aspect of the present disclosure, an apparatus for detecting a stain, includes an interface communicatively connected to an array tester, which tests a thin film transistor of a display device; a processor operatively connected to the interface; and a memory, which stores array test data received from the array tester through the interface, where the processor is configured to: receive the array test data from the interface, transform the received array test data into multiple transformation data, generate multiple images based on the multiple transformation data, respectively, and detect a location of the stain and the characteristics of the stain on the display device by comparing and analyzing the generated multiple images, and the array test data is a current value of the thin film transistor for each pixel of the display device measured using the array tester.

In an embodiment, the processor may be configured to transform the received array test data into the multiple transformation data through an operation including mathematical operations, respectively, and the mathematical operations may include arithmetic operations, differentiation, or integration.

In an embodiment, the operation may include operations, which calculate a difference between the maximum and minimum values, a mean value, a median value, a slope, a y-intersect, and an integral value of a current value of the thin film transistor for each pixel of the display device.

In an embodiment, the processor may be configured to generate the multiple images by mapping corresponding transformation data of the multiple transformation data for each pixel to a location of each pixel in the display device and correcting the corresponding transformation data into a gray scale.

In an embodiment, the processor may be configured to classify points in the generated multiple images where a brightness is a certain level or less as stain images and assign a weight to each of the classified stain images based on stain determination criteria.

In an embodiment, the processor may be configured to, when the weight assigned to each of the classified stain images is a certain level or more, classify each of the classified stain images as a stain determination image to detect a location and characteristics of the stain.

According to an aspect of the present disclosure, a method for detecting a stain of an electronic device including a display device, includes outputting array test data of the display device from an array tester; transforming the output array test data into multiple transformation data; generating multiple images based on the multiple transformation data, respectively; and determining a stain by comparing and analyzing the generated multiple images, where the array test data is a current value of a thin film transistor for each pixel of the display device measured using the array tester.

According to an aspect of the present disclosure, an apparatus for detecting a stain of an electronic device including a display device, includes an interface communicatively connected to an array tester that tests a thin film transistor of a display device; a processor operatively connected to the interface; and a memory configured to store array test data received from the array tester through the interface, the processor is configured to: receive the array test data from the interface, transform the received array test data into multiple transformation data, generate each image based on the multiple transformation data, and detect a location of the stain and the characteristics of the stain on the display device by comparing and analyzing the generated multiple images, and the array test data is a current value of the thin film transistor for each pixel of the display device measured using the array tester.

According to the apparatus and method for detecting the stain of the display device according to the embodiments, by generating multiple conversion data from one TFT array test data and comparing and analyzing multiple images in gray scale expressed based on the multiple conversion data, the stain defects of various causes occurring in the process of manufacturing the display device may be detected. Therefore, the process yield of the display device may be effectively improved.

However, the effects of the embodiments are not restricted to the one set forth herein. The above and other effects of the embodiments will become more apparent to one of daily skill in the art to which the embodiments pertain by referencing the claims.

### BRIEF DESCRIPTION OF THE DRAWINGS

The above and other aspects and features of the present disclosure will become more apparent by describing in detail embodiments thereof with reference to the attached drawings, in which:

FIG. 1 is a plan view of a display device according to an embodiment;

FIG. 2 is a circuit configuration diagram of a single pixel of the display device according to an embodiment;

FIG. 3 is a flowchart illustrating a step of detecting a stain of the display device according to an embodiment;

FIG. 4 illustrates a block diagram of an apparatus for detecting a stain of a display device according to various embodiments;

FIG. 5 is a graph illustrating array test data in the absence of stain defects according to various embodiments;

FIG. 6 is a graph illustrating first transformation data transformed by applying a first operation to the array test data of FIG. 5;

FIG. 7 is a graph illustrating array test data in the presence of stain defects according to various embodiments;

FIG. 8 is a graph illustrating first transformation data transformed by applying a first operation to the array test data of FIG. 7;

FIG. 9 is a first image generated based on the first transformation data of FIG. 8;

FIG. 10 is an enlarged view of portion B1 of FIG. 9;

FIG. 11 is a graph illustrating second transformation data transformed by applying a second operation to the array test data of FIG. 7;

FIG. 12 is a graph illustrating third transformation data transformed by applying a third operation to the array test data of FIG. 7;

FIG. 13 is a graph illustrating fourth transformation data transformed by applying a fourth operation to the array test data of FIG. 7;

FIG. 14 is a graph illustrating fifth transformation data transformed by applying a fifth operation to the array test data of FIG. 7;

FIG. 15 is a graph illustrating sixth transformation data transformed by applying a sixth operation to the array test data of FIG. 7;

FIG. 16 is a second image generated based on the second transformation data of FIG. 11;

FIG. 17 is an enlarged view of portion B3 of FIG. 16;

FIG. 18 is a third image generated based on the third transformation data of FIG. 12;

FIG. 19 is an enlarged view of portion B5 of FIG. 18;

FIG. 20 is a fourth image generated based on the fourth transformation data of FIG. 13;

FIG. 21 is an enlarged view of portion B7 of FIG. 20;

FIG. 22 is a fifth image generated based on the fifth transformation data of FIG. 14;

FIG. 23 is an enlarged view of portion B9 of FIG. 22;

FIG. 24 is a sixth image generated based on the sixth transformation data of FIG. 14;

FIG. 25 is an enlarged view of portion B11 of FIG. 24;

FIG. 26 is a diagram for describing a process of assigning a weight to each generated image;

FIG. 27 is a block diagram of an electronic display device according to an embodiment; and

FIG. 28 illustrates schematic diagrams of electronic devices according to various embodiments.

### DETAILED DESCRIPTION

The present invention will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art.

It will also be understood that when a layer is referred to as being “on” another layer or substrate, it can be directly on the other layer or substrate, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the present invention. Similarly, the second element could also be termed the first element.

Each of the features of the various embodiments of the present disclosure may be combined or combined with each other, in part or in whole, and technically various interlocking and driving are possible. Each embodiment may be implemented independently of each other or may be implemented together in an association.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof. Hereinafter, embodiments will be described with reference to the accompanying drawings.

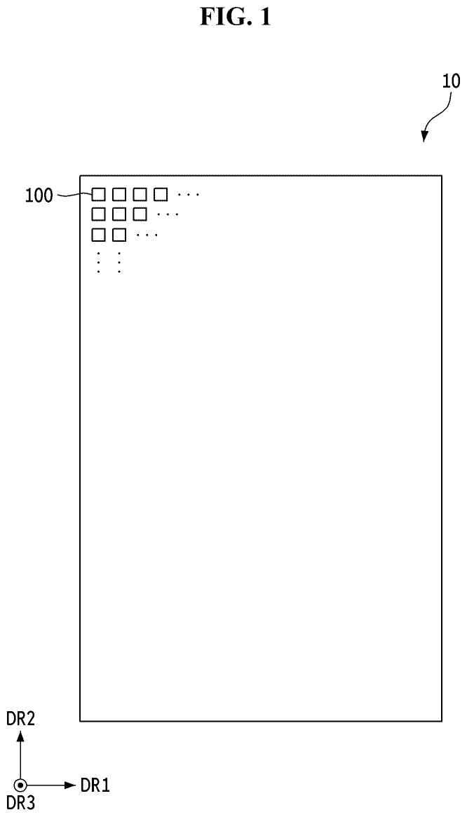

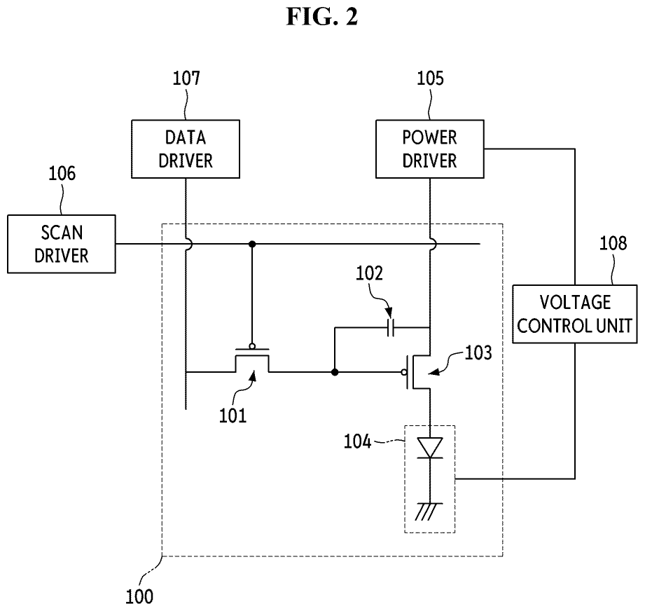

FIG. 1 is a plan view of a display device according to an embodiment. FIG. 2 is a circuit configuration diagram of a single pixel of the display device according to an embodiment.

Referring to FIG. 1, a display device 10 according to an embodiment displays a moving image or a still image. The display device 10 may refer to any display device that provides a display screen.

A shape of the display device 10 may be variously changed. For example, the display device 10 may have a shape such as a rectangle with a long width, a rectangle with a long length, a square, a quadrangle with rounded corners (vertices), other polygons, or a circle. In FIG. 1, the display device 10 having a rectangular shape with a long length in a second direction DR2 is illustrated.

The display device 10 may be a light emitting display device such as an organic light emitting display device using an organic light emitting diode, a quantum dot light emitting display device including a quantum dot light emitting layer, an inorganic light emitting display device including an inorganic semiconductor, and a micro light emitting display device using a micro or nano light emitting diode (micro or nano LED). Hereinafter, it is mainly described that the display device 10 is the organic light emitting display device, but the present disclosure is not limited thereto.

The display device 10 may include a pixel array in which a plurality of pixels 100 are arranged in a matrix form. The pixel 100 may include a pixel circuit for driving a light emitting element constituting the pixel 100.

Referring to FIG. 2, the circuit of the pixel 100 driving the display device 10 may include a first thin film transistor 101, a capacitor 102, a second thin film transistor 103, an organic light emitting element 104, a power driver 105, a scan driver 106, and a data driver 107. Such a configuration is only for convenience of explanation, and it will be apparent to those skilled in the art that the present disclosure is not limited to what is illustrated, and that a plurality of thin film transistors TFT, storage capacitors, and various types of lines may be further included.

The first thin film transistor 101 may include a switching thin film transistor. A gate electrode of the first thin film transistor 101 may be connected to the scan driver 106, and a source electrode of the first thin film transistor 101 may be connected to the data driver 107.

The second thin film transistor 103 may include a driving thin film transistor. A source electrode of the second thin film transistor 103 may be connected to the power driver 105, and a drain electrode of the second thin film transistor 103 may be connected to the organic light emitting element 104.

The first thin film transistor 101 may be driven by a scan signal applied from the scan driver 106 and may transmit a data signal applied from the data driver 107 to the second thin film transistor 103.

The second thin film transistor 103 may receive the data signal transmitted through the first thin film transistor 101 and may control the magnitude of current flowing into the organic light emitting element 104 in response to a voltage difference between the gate electrode and the source electrode. The circuit of the pixel 100 may reflect TFT characteristics, and in particular, the light emission of the display device may vary depending on the characteristics of the second thin film transistor 103.

The capacitor 102 may store the data signal transmitted through the first thin film transistor 101 for one frame.

The thin film transistors TFT are formed through multiple mask processes. A single mask process may include multiple processes, such as a thin film deposition (coating) process, a cleaning process, a photolithography process, an etching process, a strip process, and an inspection process.

In each mask process, defects due to foreign substances may occur. For example, a single pixel defect may occur when there is a defect in a thin film transistor element, pixel electrode, or other lines.

In addition, in the case where an open or short occurs between line electrodes, such as when a defective pattern caused by foreign substances remains in a mask process that forms adjacent data line and common line on the substrate, causing a defect that shorts the data line and common line, pixels connected to the data line where the defect has occurred may result in a line defect because the pixels do not operate in the entire line.

Since the single pixel defect or the line defect is usually caused by the defect in the wiring, the defects may be repaired by a method of connecting an open point when one is found and disconnecting the short point when one is found.

Therefore, in order to repair a thin film transistor (TFT) array substrate, it is necessary to detect a location where a defect has occurred. As a method for inspecting whether the TFT array substrate of such an organic light emitting diode (OLED) display device is defective, a full contact array tester may be used. The full contact array tester may test whether a pixel is defective by charging a certain amount of charge to the capacitor 102 included inside the pixel on the thin film transistor (TFT) array substrate and checking a current value output from each pixel.

However, even if the current value output through the array test is checked, it is only possible to determine whether an individual pixel is defective, and it may be difficult to detect the presence of uneven light emission defects on the entire display and the locations of the uneven light emission defects. To overcome these limitations and detect the stain defects, vision inspection may be performed. The vision inspection may be performed using human vision or high-definition camera equipment. By using the camera equipment to take an image, converting the image into data and storing the data, and then compensating for the data, the stain defects may be effectively improved. Since such a vision inspection may intuitively detect the stain defects, it may complement the limitations of the array tester that detects only whether an individual pixel is defective.

However, due to the characteristics of the display panel that is becoming thinner and simpler to output a high-quality image, there may be limitations in visual acuity test using the human body, and the vision inspection using the high-definition camera also requires the high-definition camera, which may have limitations in terms of cost and time. In addition, the vision inspection is a method of inspecting the image by lighting an organic material that emits light, and may be performed after the organic material is deposited on a glass substrate. Even if the vision inspection is performed to detect the location of the stain after the organic material is deposited on the glass substrate, it may be difficult to recycle the already deposited organic material, and such a process may result in waste of organic material and glass substrate.

According to the apparatus and method for detecting the stain according to various embodiments of the present disclosure, the presence or absence of the stain defect and the location where the stain defect occurred may be detected by converting the current value output through the array test without performing the lighting inspection. When the stain defect is detected without performing the lighting inspection, the limitations of the human body and camera equipment may be overcome. In addition, it is possible to save the cost of high-definition camera equipment, and save the organic material and the glass substrate by detecting the location where the stain defect occurred before depositing the organic material. Hereinafter, a method for detecting a stain of a display panel for detecting the presence or absence of a stain defect and the location where the stain defect occurred will be described.

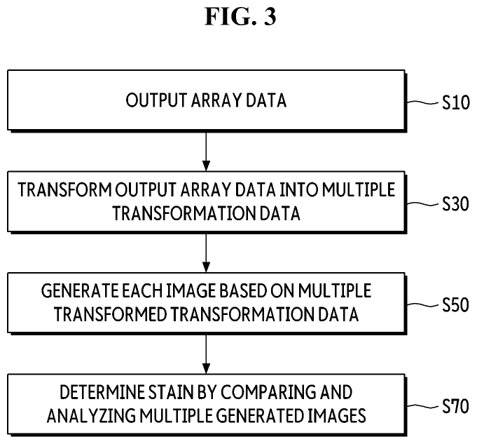

FIG. 3 is a flowchart illustrating a step of detecting a stain of the display device according to an embodiment.

Referring to FIG. 3, a method for detecting a stain of a display panel according to an embodiment may include a step of outputting TFT array test data of the display device through an array tester, a step of transforming the output test data into multiple transformation data, a step of generating each image based on multiple transformed transformation data, and a step of determining a stain by comparing and analyzing multiple generated images.

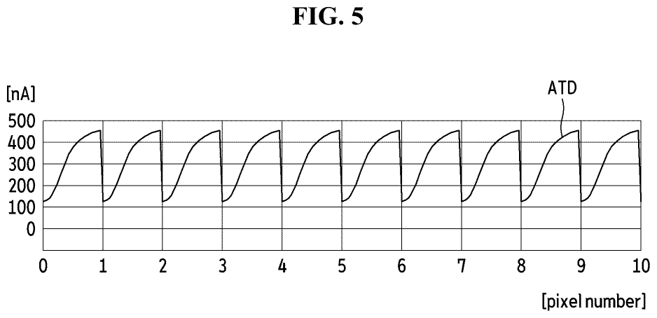

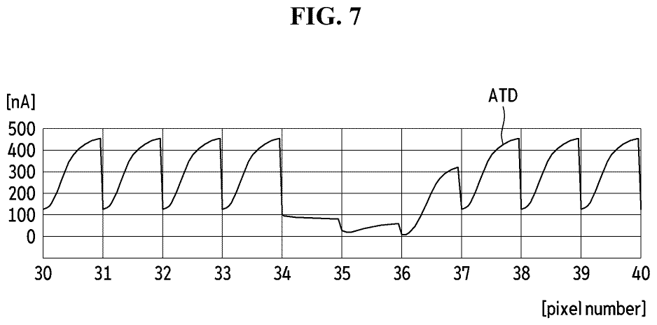

In the step (S10) of outputting the TFT array test data of the display device through the array tester, stains on a TFT array substrate of the display panel may be electrically detected using electrical array test equipment (array tester, not illustrated). The array test equipment may perform an array test on a pixel-by-pixel basis on the display panel and output test data for each line. The process of performing the array test and outputting array test data ATD has been above-mentioned in FIG. 1, and will be described through FIGS. 5 and 7 described later.

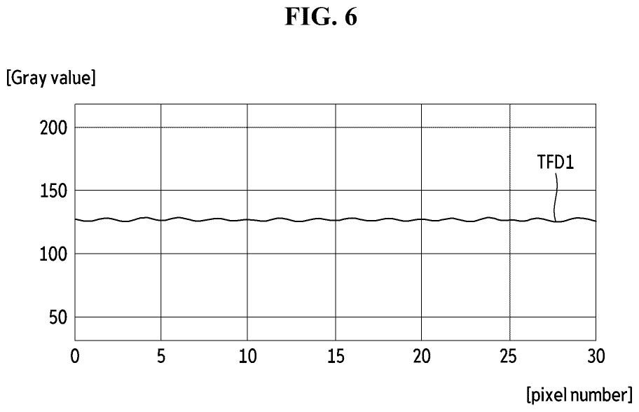

In the step (S30) of transforming the output test data into the multiple transformation data, an array tester result (array test data ATD) may be transformed into multiple transformation data TFD through an operation process according to various embodiments to detect the presence or absence of the stain defects and the locations where the defects occurred. The operation process may use various mathematical operations such as arithmetic operations, differentiation, and integration. In some embodiments, the operation process may be an operation that calculates a difference between the maximum and minimum values of the test data for each pixel. Alternatively, in some embodiments, the operation process may be an operation that calculates the mean value of the test data for each pixel. Alternatively, in some embodiments, the operation process may be an operation that calculates a median of the test data for each pixel. Alternatively, in some embodiments, the operation process may be an operation that calculates a slope, such as an average rate of change or an instantaneous rate of change. Alternatively, in some embodiments, the operation process may be an operation that calculates a y-intercept of a straight line whose slope is the average rate of change or the instantaneous rate of change of the test data for each pixel. Alternatively, in some embodiments, the operation process may be an operation that calculates an integral value of the test data for each pixel. By using various operation methods, an operation value may be generated on a pixel-by-pixel basis, and by naming the operation value as a gray value, the transformation data TFD with a gray value or each pixel may be generated. The transformation data TFD may have a specific range of gray values depending on the operations applied to the operation processes according to various embodiments. In addition, the transformation data TFD may be illustrated as a graph of a specific waveform depending on the operations applied to the operation processes according to various embodiments. The process of transforming from the array test data ATD to the transformation data TFD will be described through FIGS. 6, 8, and 11 to 15 described later.

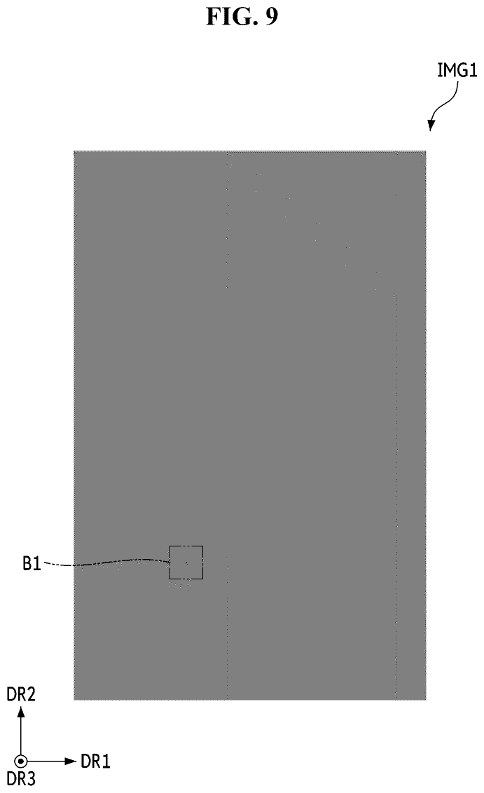

In the step (S50) of generating each image based on the multiple transformed transformation data TFD, the transformation data TFD transformed into the gray value for each pixel may be imaged at a set scale to represent an image IMG of the display device in which the corresponding pixels are continuously connected. Here, the set scale may include a gray scale with values between 0 and 255. The gray scale transformation may represent each pixel value of an image as a value between 0 and 255, where 0 may mean black and 255 may mean white. Specifically, a pixel whose corrected gray value is close to 0 may be expressed as a color close to black between white and black, and a pixel whose corrected gray value is close to 255 may be expressed as a color close to white between white and black. The process of transforming the transformation data TFD into the gray scale image IMG will be described through FIGS. 9, 16, 18, 20, 22, and 24 described later.

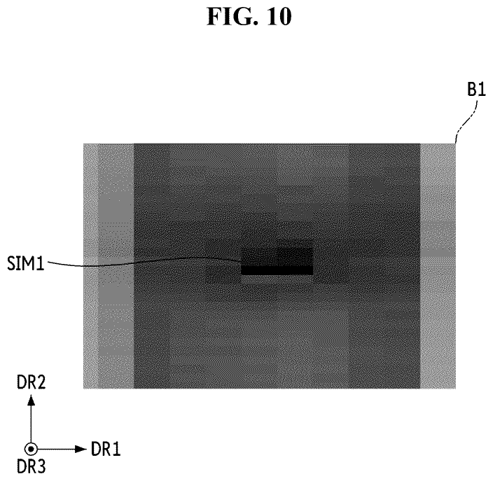

In the step (S70) of determining the stain by comparing and analyzing the multiple generated images, the stain may be determined by classifying points with brightness of a certain level or less in each gray scale image IMG generated from the multiple transformation data TFD as stain images SIM, assigning weights to each of the classified multiple stain images SIM, classifying at least one stain image SIM with a weighting value of a certain level or more among the multiple stain images SIM as a stain determination image, comparing the classified stain determination images, and analyzing a location and characteristics of the stain. In some embodiments, in the process of assigning the weights to the multiple stain images SIM and classifying the stain determination image from the multiple stain images SIM, various algorithmic formulas may be applied. The process of determining the stain by comparing and analyzing the multiple generated images will be described through FIGS. 10, 17, 19, 21, 23, 25, and 26 described later.

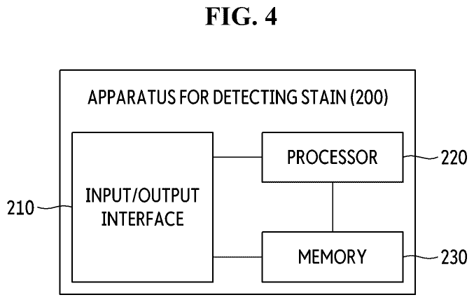

FIG. 4 illustrates a block diagram of an apparatus for detecting a stain of a display device according to various embodiments.

Referring to FIG. 4, an apparatus 200 for detecting a stain of a display device may include an input/output interface 210, a processor 220 operatively connected to the input/output interface 210, and a memory 230, and some of the illustrated configurations may be omitted or substituted.

The input/output interface 210 may be used to connect directly or wirelessly with an electronic device (e.g., the array test equipment). To this end, the input/output interface 210 may support one or more designated protocols. For example, the supportable protocols of the input/output interface 210 may include a high definition multimedia interface (HDMI), a universal serial bus (USB) interface, an SD card interface, or an audio interface.

According to an embodiment, the input/output interface 210 may receive test result information from the array test equipment and transmit the test result information to the processor 220 and the memory 230 inside the apparatus 200 for detecting the stain. In addition, the input/output interface 210 may be communicatively connected to the TFT array tester for testing the thin film transistor of the display device.

According to various embodiments, the memory 230 may include known volatile memory and non-volatile memory, and is not limited in specific implementation examples. The memory 230 may store various instructions that may be performed by the processor 220. Such instructions may include various control commands including arithmetic and logical operations, data movement, and input/output that may be recognized by the processor 220. According to an embodiment, the memory 230 may store the array test result information received from the input/output interface 210.

According to various embodiments, the processor 220 may include a configuration capable of performing operations or data processing related to control and/or communication of each component of the apparatus 200 for detecting the stain. The processor 220 may be functionally, operatively, and/or electrically connected to internal components of the apparatus 200 for detecting the stain of the display panel and memory 230.

There is no limitation to the operation and data processing functions that the processor 220 may implement within the apparatus 200 for detecting the stain, but in the present specification, various embodiments for processing an operation of transforming test data ATD acquired after the thin film transistor (TFT) process into multiple transformation data TFD, generate an image IMG of each gray scale based on the multiple transformation data TFD, and detecting the stain by comparing and analyzing the images will be described. The TFT process for forming the thin film transistor (TFT) has been described in FIG. 2 above. The operations of the processor 220 to be described later may be performed by loading the instructions stored in the memory 230.

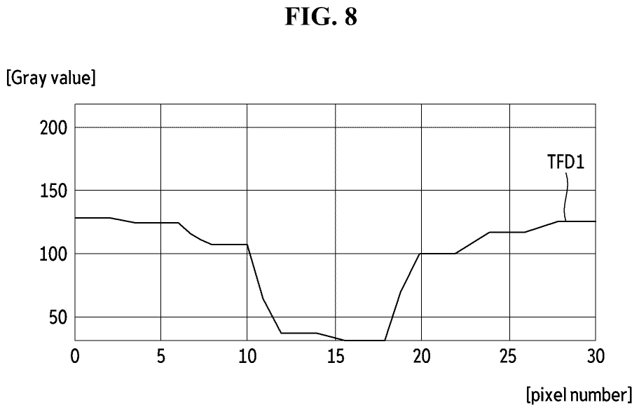

According to various embodiments, the array test equipment may perform an array test on a pixel-by-pixel basis on the display panel and output test data ATD. The process of performing the array test and outputting the array test data ATD has been mentioned in FIGS. 2 and 3, and will be described through FIGS. 5 and 7. The processor 220 may receive array tester results (test data ATD) and perform an operation for detecting the presence or absence of a stain defect and a location of the defect. This operation process and the process of detecting the stain through the operation will be described through FIGS. 8 to 26 described later.

According to various embodiments, the processor 220 may transform the test data ATD into a gray value for each pixel to generate transformation data TFD. The method for generating the transformation data TFD has been previously mentioned in FIG. 3 and will be described in FIGS. 6, 8, and 11 to 15.

According to various embodiments, the processor 220 may transform the transformation data TFD into a set scale to generate corrected transformation data. Here, the set scale may include a gray scale with values between 0 and 255. The processor 220 may generate an image IMG based on the corrected transformation data.

According to an embodiment, the processor 220 may generate an image IMG by dividing the size of the display panel by the number of pixels to determine a size of each pixel, distinguishing the location of pixels on the display panel for each determined size of the pixel, displaying the corrected transformation data for each pixel to correspond to the location of the thin film transistor, and displaying the corrected transformation data displayed on a pixel-by-pixel basis to have a brightness corresponding to the gray scale.

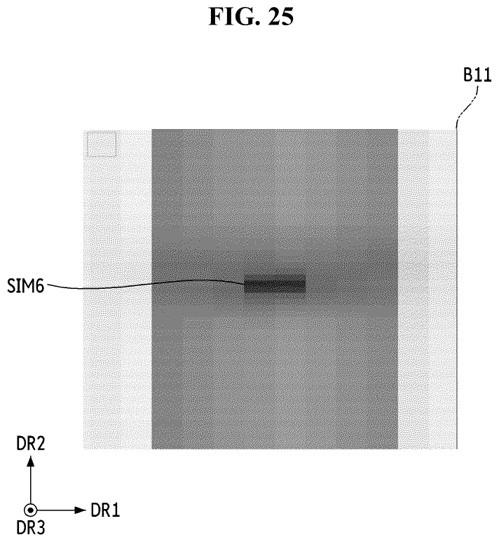

According to various embodiments, the processor 220 may detect a stain on the display device 10 by comparing and analyzing the multiple generated images IMG. The stain on the display device 10 may be classified as a stain through a process of assigning weights to each type of generated image IMG, and the classification process has been previously mentioned in FIG. 3 and will be described through FIG. 25 described later.

FIG. 5 is a graph illustrating array test data in the absence of stain defects according to various embodiments.

Referring to FIG. 5, in the step (S10) of outputting the TFT array test data of the display device through the array tester, a constant pattern of output may be obtained by applying a constant voltage (e.g., 5 V) to the TFT circuit of the display device. As illustrated in FIG. 5, the array test data ATD may be illustrated as a graph, with an x-axis representing the pixel numbers of corresponding pixels and a y-axis representing an output current value (nanoamperes: nA). Referring to FIG. 5, when there is no stain defect, it may be confirmed that the output pattern on a pixel-by-pixel is consistently formed.

FIG. 6 is a graph illustrating first transformation data transformed by applying a first operation to the array test data of FIG. 5.

Referring to FIG. 6, in the step (S30) of transforming the output test data into the multiple transformation data, the array test data ATD may be transformed into first transformation data TFD1 through a first operation process. The first operation process may be performed as a first operation that calculates a difference between the maximum and minimum values of the test data for each pixel. In some embodiments, the difference between the maximum and minimum values of the test data for each pixel may be a difference between the maximum and minimum values of a current value for each pixel. When there is no stain defect as illustrated in FIG. 5 above, the output pattern of the test data on a pixel-by-pixel basis is constant, and thus a result value of the first operation for each pixel may have a constant value. Referring to FIG. 6, when there are no stains, it may be confirmed that the gray value for each pixel is consistently formed.

FIG. 7 is a graph illustrating array test data in the presence of stain defects according to various embodiments. FIG. 8 is a graph illustrating first transformation data transformed by applying a first operation to the array test data of FIG. 7.

Hereinafter, the differences will be mainly described and duplicated descriptions will be omitted.

First, referring to FIG. 7, when there are stain defects, compared to FIG. 5, the output pattern on a pixel-by-pixel basis may be inconsistently formed. Referring to FIG. 6, it may be confirmed that the output pattern of pixels without stain defects is constant, but the output pattern of pixels with stain defects is formed differently compared to normal pixels.

Next, referring to FIG. 8, compared to FIG. 6, when there are stain defects, the gray values for each pixel of the first transformation data TFD1 transformed from the array test data ATD through the first operation process may not be constant. Referring to FIG. 7, it may be confirmed that the gray value of pixels without stain defects is constant, but the gray value of pixels with stain defects is formed differently compared to normal pixels.

FIG. 9 is a first image generated based on the first transformation data of FIG. 8. FIG. 10 is an enlarged view of portion B1 of FIG. 9.

Referring to FIGS. 9 and 10, in the step (S50) of generating each image based on the multiple transformed transformation data and the step (S70) of determining the stain by comparing and analyzing the multiple generated images, the first transformation data TFD1 may be represented as a first image IMG1 by mapping the first transformation data TFD1 for each pixel to the location of each pixel in the display device 10 in which the pixels are continuously connected. The first transformation data TFD1 illustrated in FIG. 8 may be represented as a gray scale having a value between 0 and 255, where 0 may mean black and 255 may mean white as shown in FIGS. 9 and 10. In this case, in the first image IMG1 expressed in the gray scale, a portion with lower brightness than surroundings thereof may be classified as a location where there is a stain. Referring to FIGS. 9 and 10, in the portion B1, a portion expressed in a color closer to black than the surrounding area may be classified as a location where there is a stain, and a first stain image SIM1 that is distinct from surrounding points in brightness may be identified.

In this way, visibility of the presence or absence of the stain defects and the locations of stain defects may be secured, but since depending on the applied operation, the gray value of the transformation data TFD may appear in a narrow range, and the difference in brightness between the pixel where the stain defects are located and the normal pixel in the image IMG obtained by imaging the transformation data TFD at the gray scale is not clear, there may be limitations in accurately detecting the stain.

Therefore, as multiple transformation data TFD each having a different specific range of gray values is generated by applying various operations from one array test data ATD, and each of the multiple transformation data TFD is imaged, it is possible to express various stain images SIM, and in particular, stains occurring in low-level tones may be clearly expressed and detected.

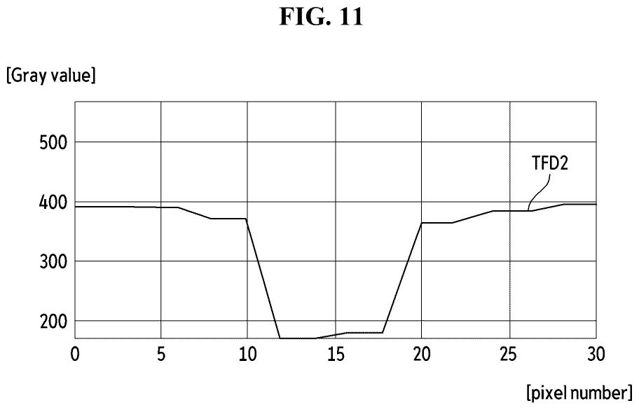

FIGS. 11 to 15 are graphs illustrating transformation data transformed by applying operations according to various embodiments to the array test data of FIG. 7.

Hereinafter, the differences will be mainly described and duplicated descriptions will be omitted.

FIG. 11 is a graph illustrating second transformation data transformed by applying a second operation to the array test data of FIG. 7.

Referring to FIG. 11, the array test data ATD may be transformed into second transformation data TFD2 through a second operation process. The second operation process may be performed as a second operation that calculates the mean value of the test data for each pixel. In some embodiments, the mean value of the test data for each pixel may be a difference between the maximum and minimum current values of the thin film transistor for each pixel. Referring to FIG. 11, compared to FIG. 8, it may be confirmed that a graph of a different waveform in which the second transformation data TFD2 has a different range of gray values from the same array test data ATD is formed.

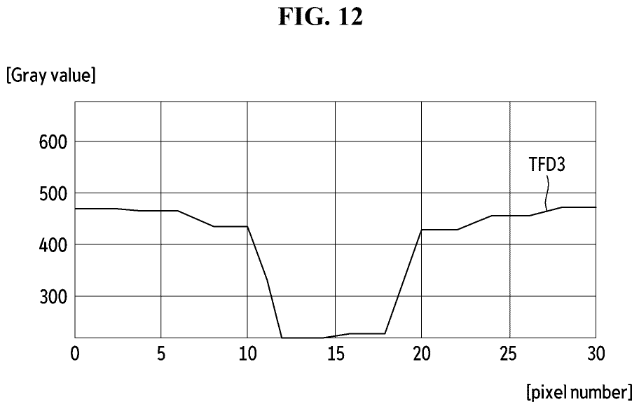

FIG. 12 is a graph illustrating third transformation data transformed by applying a third operation to the array test data of FIG. 7.

Referring to FIG. 12, the array test data ATD may be transformed into third transformation data TFD3 through a third operation process. The third operation process may be performed as a third operation that calculates the median of the test data for each pixel. In some embodiments, the median of the test data for each pixel may be a median of the current value of the thin film transistor for each pixel. Referring to FIG. 12, compared to FIG. 8, it may be confirmed that a graph of a different waveform in which the third transformation data TFD3 has a different range of gray values from the same array test data ATD is formed.

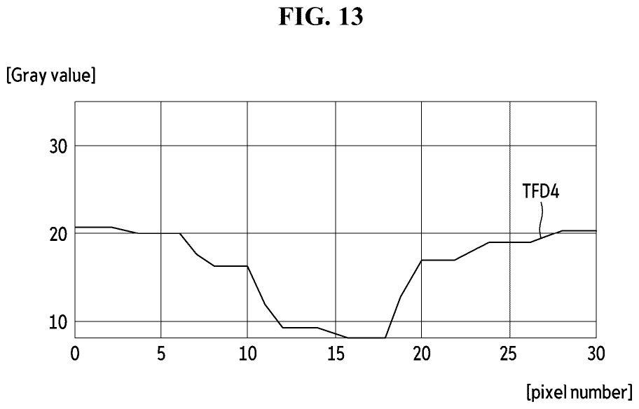

FIG. 13 is a graph illustrating fourth transformation data transformed by applying a fourth operation to the array test data of FIG. 7.

Referring to FIG. 13, the array test data may be transformed into fourth transformation data TFD4 through a fourth operation process. The fourth operation process may be performed as a fourth operation that calculates a slope of the test data for each pixel. In some embodiments, the slope of the test data for each pixel may be an average rate of change of the current value of the thin film transistor for each pixel. Alternatively, in some embodiments, the slope of the test data for each pixel may be an instantaneous rate of change of the current value of the thin film transistor for each pixel. Referring to FIG. 13, compared to FIG. 8, it may be confirmed that a graph of a different waveform in which the fourth transformation data TFD4 has a different range of gray values from the same array test data ATD is formed.

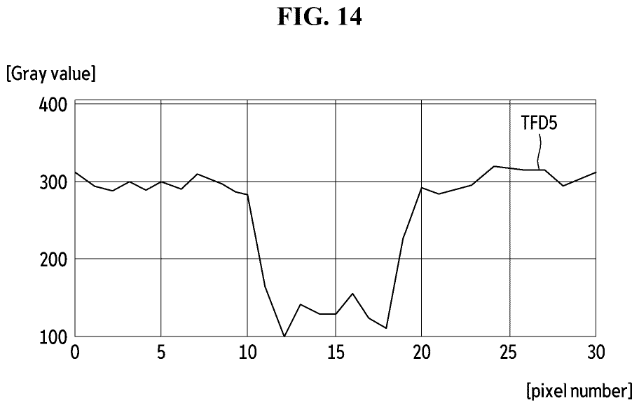

FIG. 14 is a graph illustrating fifth transformation data transformed by applying a fifth operation to the array test data of FIG. 7.

Referring to FIG. 14, the array test data ATD may be transformed into fifth transformation data TFD5 through a fifth operation process. The fifth operation process may be performed as a fifth operation that calculates a y-intercept of the test data for each pixel. In some embodiments, the y-intercept of the test data for each pixel may be a y-intercept of a straight line whose slope is the average rate of change of the test data for each pixel Alternatively, in some embodiments, the y-intercept of the test data for each pixel may be a y-intercept of a straight line whose slope is the instantaneous rate of change of the current value of the thin film transistor for each pixel. Referring to FIG. 14, compared to FIG. 8, it may be confirmed that a graph of a different waveform in which the fifth transformation data TFD5 has a different range of gray values from the same array test data ATD is formed.

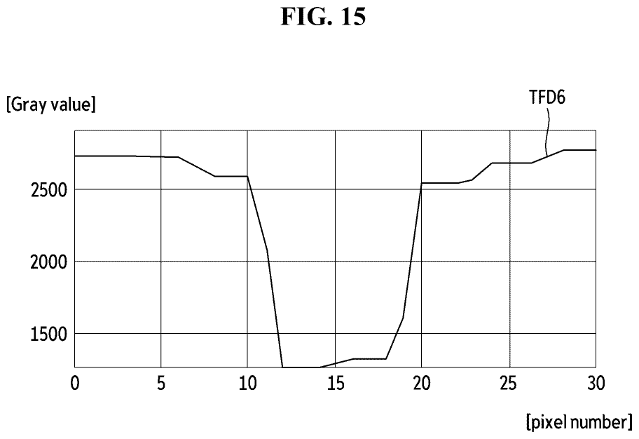

FIG. 15 is a graph illustrating sixth transformation data transformed by applying a sixth operation to the array test data of FIG. 7.

Referring to FIG. 15, the array test data ATD may be transformed into sixth transformation data TFD6 through a sixth operation process. The sixth operation process may be performed as a sixth operation that calculates an integral value of a graph (or function) illustrating the test data for each pixel. In some embodiments, the integral value of the graph illustrating the test data for each pixel may be a definite integral value of a graph (or function) illustrating the current value of the thin film transistor for each pixel. Referring to FIG. 15, compared to FIG. 8, it may be confirmed that a graph of a different waveform in which the sixth transformation data TFD6 has a different range of gray values from the same array test data ATD is formed.

As illustrated in FIGS. 8 and 11 to 15, in the step (S30) of transforming the output test data into the multiple transformation data, it may be confirmed that each transformation data TFD with different ranges of gray values and different waveforms is generated by applying each different operation from one array test data ATD, and this may be visualized in a gray-scale image IMG generated based on the transformation data TFD.

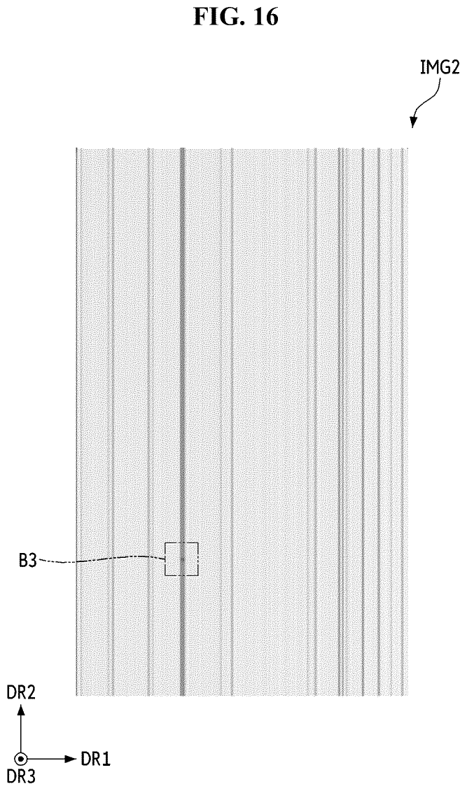

FIGS. 16 to 25 are diagrams for describing respective images generated based on the transformation data according to various embodiments of FIGS. 11 to 15.

Hereinafter, the differences will be mainly described and duplicated descriptions will be omitted.

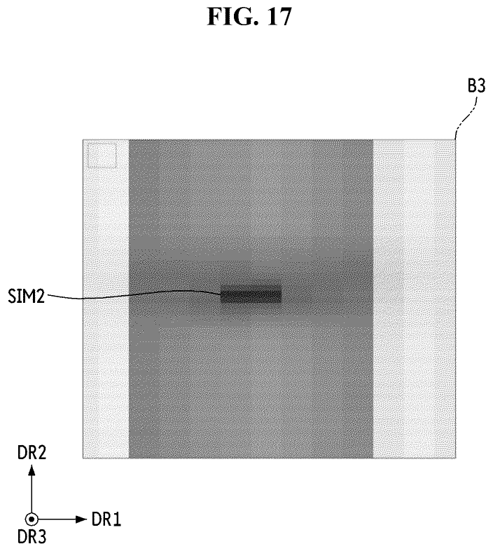

FIG. 16 is a second image generated based on the second transformation data of FIG. 11. FIG. 17 is an enlarged view of portion B3 of FIG. 16.

Referring to FIGS. 16 and 17, a second image IMG2 and a second stain image SIM2 of gray scale expressed with another brightness difference from the same array test data ATD may be confirmed compared to FIGS. 9 and 10.

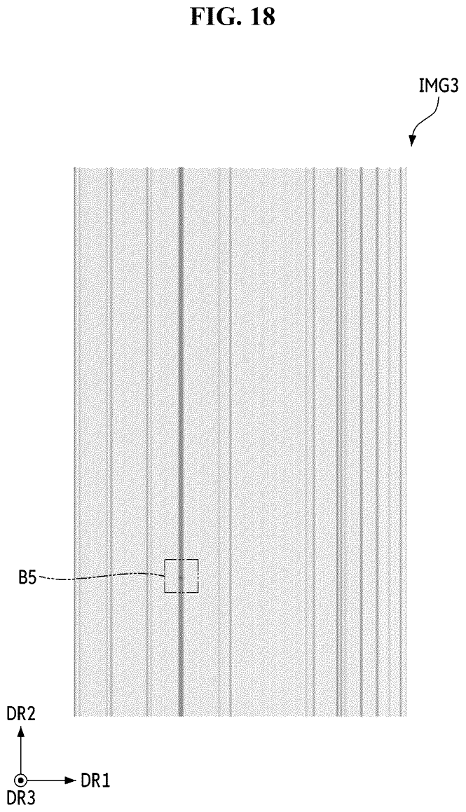

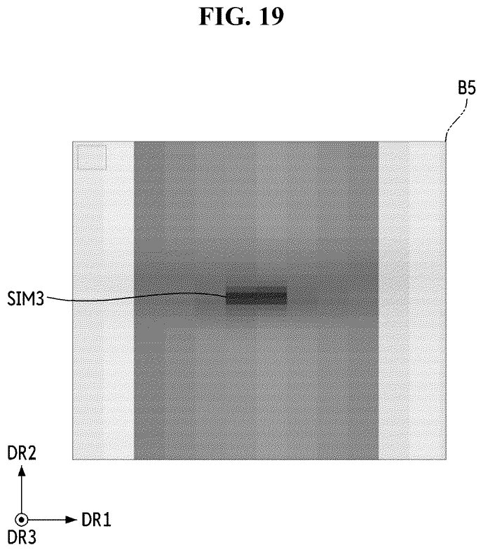

FIG. 18 is a third image generated based on the third transformation data of FIG. 12. FIG. 19 is an enlarged view of portion B5 of FIG. 18.

Referring to FIGS. 18 and 19, a third image IMG3 and a third stain image SIM3 of gray scale expressed with still another brightness difference from the same array test data ATD may be confirmed compared to FIGS. 9 and 10.

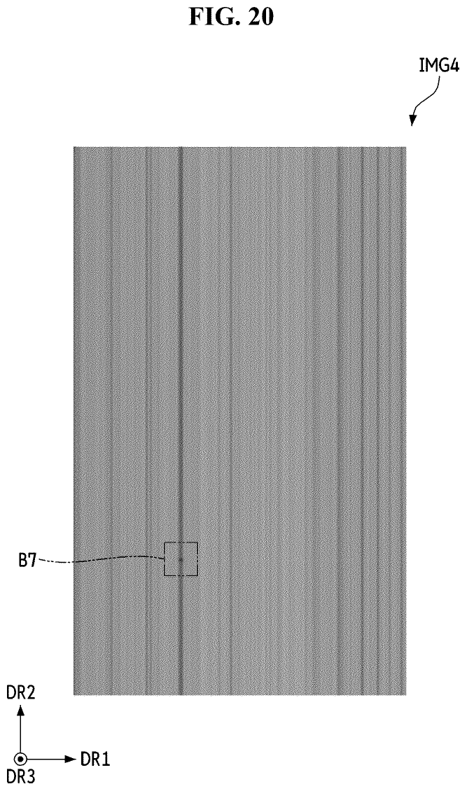

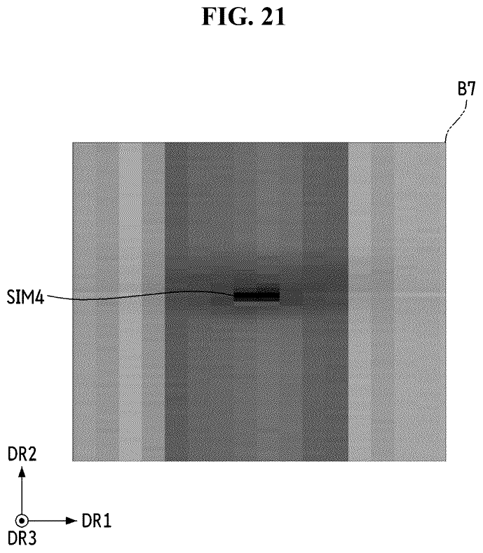

FIG. 20 is a fourth image generated based on the fourth transformation data of FIG. 13. FIG. 21 is an enlarged view of portion B7 of FIG. 20.

Referring to FIGS. 20 and 21, a fourth image IMG4 and a fourth stain image SIM4 of gray scale expressed with still another brightness difference from the same array test data ATD may be confirmed compared to FIGS. 8 and 9.

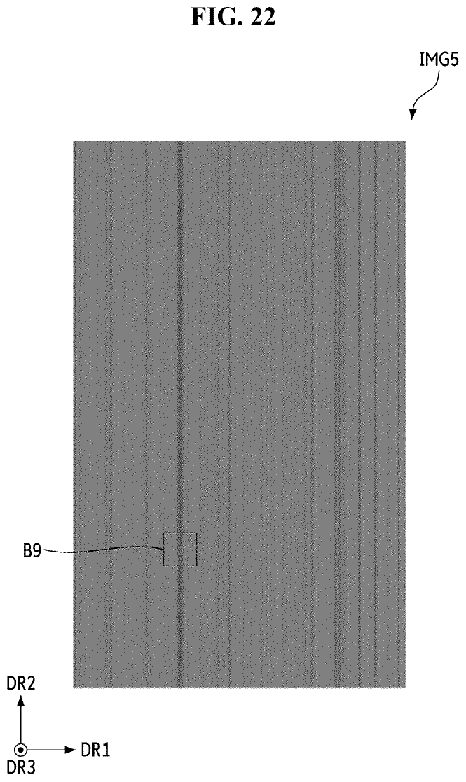

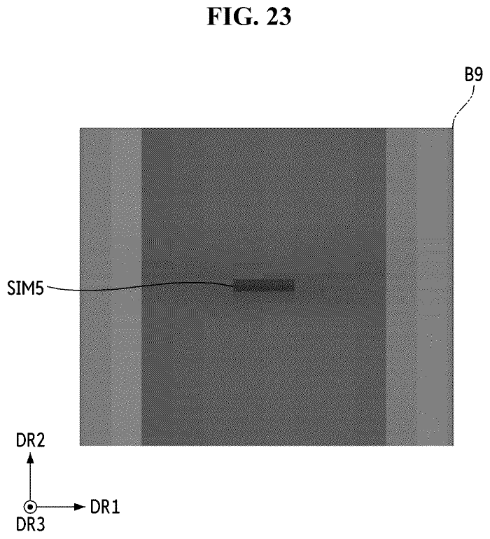

FIG. 22 is a fifth image generated based on the fifth transformation data of FIG. 14. FIG. 23 is an enlarged view of portion B9 of FIG. 22.

Referring to FIGS. 22 and 23, a fifth image IMG5 and a fifth stain image SIM5 of gray scale expressed with still another brightness difference from the same array test data ATD may be confirmed compared to FIGS. 9 and 10.

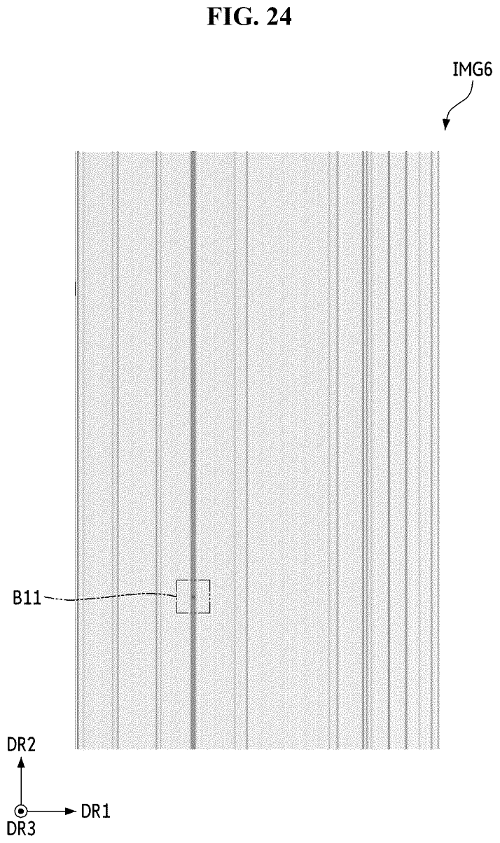

FIG. 24 is a sixth image generated based on the sixth transformation data of FIG. 14. FIG. 25 is an enlarged view of portion B11 of FIG. 24.

Referring to FIGS. 24 and 25, a sixth image IMG6 and a sixth stain image SIM6 of gray scale expressed with still another brightness difference from the same array test data ATD may be confirmed compared to FIGS. 8 and 9.

As illustrated in FIGS. 9, 10, and 16 to 25, in the step (S50) of generating each image based on the multiple transformed transformation data, it is possible to generate images IMG1, IMG2, IMG3, IMG4, IMG5, and IMG6 each representing different brightness differences from one array test data ATD, and this allows for improved expression of stains of various causes, thereby further securing the visibility of stain defects.

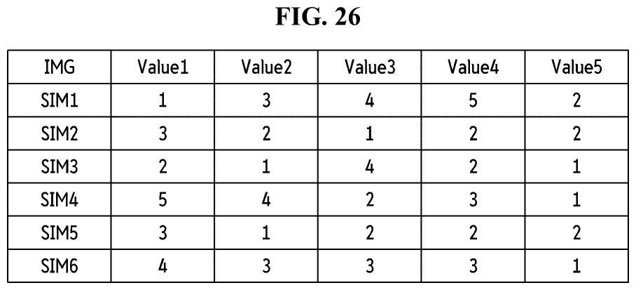

FIG. 26 is a diagram for describing a process of assigning a weight to each generated image.

Referring to FIG. 26, in the step (S70) of determining the stain by comparing and analyzing the multiple generated images, the stain may be finally determined by classifying points with brightness of a certain level or less in each generated image IMG, assigning weights to each of the classified multiple stain images SIM, classifying only stain images with a assigned weighting value of a certain level or more as a stain determination image again, comparing the classified stain determination images, and analyzing a location and characteristics of the stain.

Referring to FIG. 26, it may be confirmed that points in the generated multiple images IMG1, IMG2, IMG3, IMG4, IMG5, and IMG6 whose brightness is a certain level or less are classified as the stain images SIM1, SIM2, SIM3, SIM4, SIM5, and SIM6 and weights expressed as scores according to various stain determination criteria value1, value2, value3, value4, and value5 are assigned.

The stains of a wider variety of causes may be accurately determined by classifying only the stain images with a weight assigned through the process of assigning the weight to each generated image is a certain level or more as the stain determination images again and comparing and analyzing the stain determination images. Therefore, since various causes of stain defects occurring during the process of manufacturing the display device may be more accurately detected, a process yield of the display device may be effectively improved.

The display device according to the embodiment may be applied to various electronic devices. The display device according to the embodiment may be applied to various electronic devices.

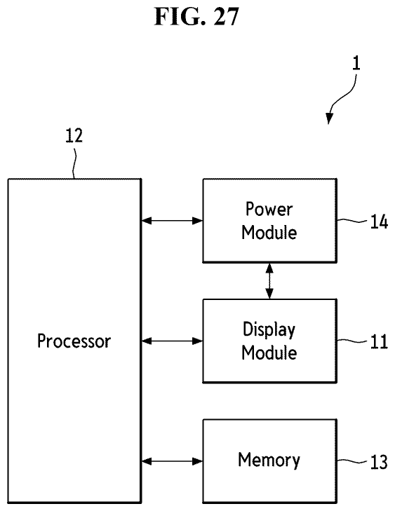

FIG. 27 is a block diagram of an electronic display device according to an embodiment.

Referring to FIG. 27, an electronic device 1 according to an embodiment may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

Data information necessary for an operation of the processor 12 or the display module 11 may be stored in the memory 13. When the processor 12 executes an application stored in the memory 13, image data signals and/or input control signals may be transmitted to the display module 11, and the display module 11 may process the provided signals and output image information through a display screen.

The power module 14 may include a power supply module, such as a power adapter or a battery device, and a power conversion module that converts power supplied by the power supply module to generate power required for an operation of the electronic device 1.

At least one of the components of the electronic device 1 described above may be included in the display device according to the above-described embodiments. In addition, some of the individual modules functionally included within one module may be included within the display device, while others may be provided separately from the display device. For example, the display device includes the display module 11, and the processor 12, the memory 13, and the power module 14 may be provided in the form of other devices within the electronic device 1 other than the display device.

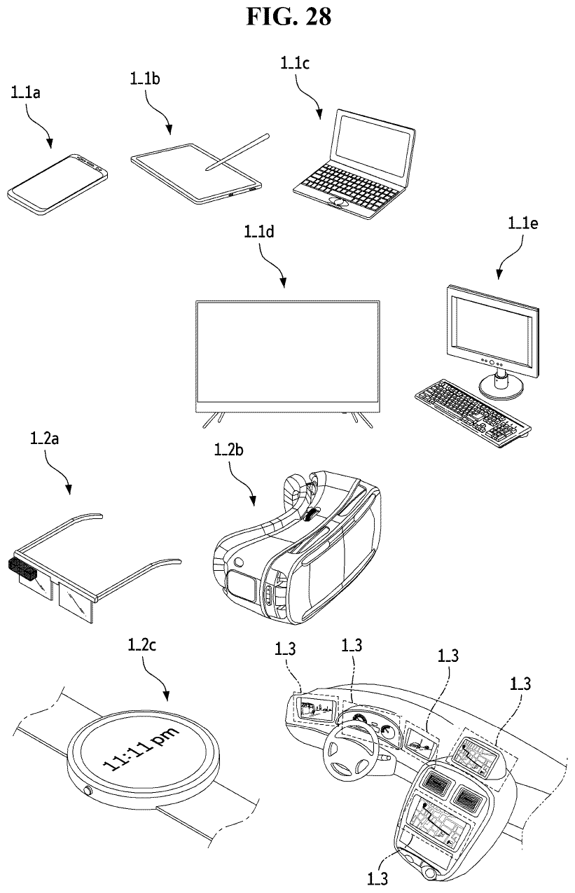

FIG. 28 illustrates schematic diagrams of electronic devices according to various embodiments.

Referring to FIG. 28, various electronic devices to which the display device according to the embodiments is applied may include not only an image display electronic device such as a smart phone 1_1a, a tablet PC 1_1b, a laptop 1_1c, a TV 1_1d, and a desk monitor 1_1e, but also a wearable electronic device including a display module such as a smart glasses 1_2a, a head mounted display 1_2b, a smart watch 1_2c, and the like, and a vehicle electronic device 1_3 including a display module such as a Center Information Display (CID), a room mirror display, etc., disposed on a vehicle's instrument panel, center fascia, or dashboard.

In concluding the detailed description, those skilled in the art will appreciate that many variations and modifications can be made to the preferred embodiments without substantially departing from the principles of the present invention. Therefore, the disclosed preferred embodiments of the invention are used in a generic and descriptive sense only and not for purposes of limitation.

What is claimed is:

1. A method for detecting a stain of a display device, the method comprising:
outputting array test data of the display device from an array tester;
transforming the output array test data into multiple transformation data;
generating multiple images based on the multiple transformation data, respectively; and
determining a stain by comparing and analyzing the generated multiple images,
wherein the array test data is a current value of a thin film transistor for each pixel of the display device measured using the array tester.

2. The method of claim 1, wherein in the transforming of the output array test data into the multiple transformation data,
the output array test data is transformed into the multiple transformation data through an operation including mathematical operations, respectively,
wherein the mathematical operations include arithmetic operations, differentiation, or integration.

3. The method of claim 2, wherein the operation includes a first operation, and the first operation calculates a difference between a maximum value and a minimum value of the current value of the thin film transistor for each pixel of the display device.

4. The method of claim 2, wherein the operation includes a second operation, and the second operation calculates a mean value of the current value of the thin film transistor for each pixel of the display device.

5. The method of claim 2, wherein the operation includes a third operation, and the third operation calculates a median value of the current value of the thin film transistor for each pixel of the display device.

6. The method of claim 2, wherein the operation includes a fourth operation, and the fourth operation calculates an average rate of change or an instantaneous rate of change of the current value of the thin film transistor for each pixel of the display device.

7. The method of claim 2, wherein the operation includes a fifth operation, and the fifth operation calculates a y-intercept of a straight line whose slope is an average rate of change or an instantaneous rate of change of the current value of the thin film transistor for each pixel of the display device.

8. The method of claim 2, wherein the operation includes a sixth operation, and the sixth operation calculates a definite integral value of the current value of the thin film transistor for each pixel of the display device.

9. The method of claim 1, wherein the generating of the multiple images based on the multiple transformation data, respectively, comprises:
mapping corresponding transformation data of the multiple transformation data for each pixel to a location of each pixel in the display device and correcting the corresponding transformation data into a gray scale.

10. The method of claim 1, wherein the determining of the stain by comparing and analyzing the generated multiple images comprises:
classifying points in the generated multiple images where a brightness is a certain level or less as stain images; and
assigning a weight to each of the classified stain images based on stain determination criteria.

11. The method of claim 10, wherein the determining of the stain by comparing and analyzing the generated multiple images further comprises:
when the weight assigned to each of the classified stain images is a certain level or more, classifying each of the classified stain image as a stain determination image.

12. The method of claim 11, wherein the determining of the stain by comparing and analyzing the generated multiple images further comprises:
finally determining the stain by comparing the classified stain determination images and analyzing a location and characteristics of the stain.

13. An apparatus for detecting a stain, the apparatus comprising:
an interface communicatively connected to an array tester, which tests a thin film transistor of a display device;
a processor operatively connected to the interface; and
a memory, which stores array test data received from the array tester through the interface,
wherein the processor is configured to:
receive the array test data from the interface,
transform the received array test data into multiple transformation data,
generate multiple images based on the multiple transformation data, respectively, and
detect a location of the stain and characteristics of the stain on the display device by comparing and analyzing the generated multiple images, and
wherein the array test data is a current value of the thin film transistor for each pixel of the display device measured using the array tester.

14. The apparatus of claim 13, wherein the processor is configured to transform the received array test data into the multiple transformation data through an operation including mathematical operations, respectively, and the mathematical operations include arithmetic operations, differentiation, or integration.

15. The apparatus of claim 14, wherein the operation includes operations, which calculate a difference between a maximum value and a minimum value, a mean value, a median value, a slope, a y-intersect, and an integral value of a current value of the thin film transistor for each pixel of the display device.

16. The apparatus of claim 13, wherein the processor is configured to generate the multiple images by mapping corresponding transformation data of the multiple transformation data for each pixel to a location of each pixel in the display device and correcting the corresponding transformation data into a gray scale.

17. The apparatus of claim 13, wherein the processor is configured to classify points in the generated multiple images where a brightness is a certain level or less as stain images and assign a weight to each of the classified stain images based on stain determination criteria.

18. The apparatus of claim 17, wherein the processor is configured to, when the weight assigned to each of the classified stain images is a certain level or more, classify each of the classified stain images as a stain determination image to detect a location and characteristics of the stain.

19. A method for detecting a stain of an electronic device including a display device, the method comprising:
outputting array test data of the display device from an array tester;
transforming the output array test data into multiple transformation data;
generating multiple images based on the multiple transformation data, respectively; and
determining a stain by comparing and analyzing the generated multiple images,
wherein the array test data is a current value of a thin film transistor for each pixel of the display device measured using the array tester.

20. The method of claim 19, wherein in the transforming of the output array test data into the multiple transformation data,
the output array test data is transformed into the multiple transformation data through an operation including mathematical operations, respectively,
wherein the mathematical operations include arithmetic operations, differentiation, or integration.
